(19) United States
(12) Patent Application Publication
(10) Pub. No.: US 2018/0148338 A1
(43) Pub. Date: May 31, 2018

(54) METHOD FOR FORMING HETEROJUNCTION STRUCTURE OF GRAPHENE AND TWO-DIMENSIONAL MATERIAL

(71) Applicant: ELECTRONICS AND TELECOMMUNICATIONS RESEARCH INSTITUTE, Daejeon (KR)

(72) Inventor: Young-Jun YU, Daejeon (KR)

(21) Appl. No.: 15/792,621

(22) Filed: Oct. 24, 2017

(30) Foreign Application Priority Data
Nov. 25, 2016 (KR) 10-2016-0158638
Apr. 4, 2017 (KR) 10-2017-0043842

(51) Int. Cl. C01B 32/184; H01B 1/02

(52) U.S. Cl. CPC C01B 32/184; H01L 29/1606; H01B 1/02

(57) ABSTRACT

A method for forming a heterojunction structure of graphene and a two-dimensional material is provided. The method includes providing a graphene pattern on a substrate, applying a current to the graphene pattern to heat the graphene pattern, and forming a two-dimensional material layer on the graphene pattern.

### CROSS-REFERENCE TO RELATED APPLICATION

This U.S. non-provisional patent application claims priority under 35 U.S.C. § 119 to Korean Patent Application Nos. 10-2016-0158638 and 10-2017-0043842, filed on Nov. 25, 2016 and Apr. 4, 2017, in the Korean Intellectual Property Office, the disclosure of which is hereby incorporated by reference in its entirety.

### BACKGROUND

Embodiments of the inventive concepts relate to a method for forming a heterojunction structure of graphene and a two-dimensional material.

Recently, heterojunction structures using nanomaterials have been very attractive in materials engineering and physics. One of them is a van der Waals heterojunction structure in which two-dimensional materials having thicknesses of atomic layers (e.g., several angstroms) are bonded to each other.

The van der Waals heterojunction structure may include different kinds of two-dimensional materials which are sequentially stacked. In the van der Waals heterojunction structure, atoms in each of the two-dimensional materials may be covalently bonded to each other and the two-dimensional materials may be bonded to each other by the van der Waals force (or van der Waals bonds). The van der Waals heterojunction structure is known to exhibit new and unusual properties by the quantum confinement effect according to the two-dimensional material having the thickness of the atomic layer and the interaction between two-dimensional material layers through an interface thereof, unlike a conventional bulk heterojunction structure.

According to a widely used method of forming a heterojunction structure, two-dimensional materials are grown on different substrates, respectively, and then one two-dimensional material is transferred onto another two-dimensional material. However, in this method, the quality and the yield of the heterojunction structure may be deteriorated by processes of laminating and transferring the two-dimensional material.

### SUMMARY

Embodiments of the inventive concepts may provide a method for forming a heterojunction structure of graphene and a two-dimensional material, which is capable of simplifying formation processes.

Embodiments of the inventive concepts may also provide a method for forming a heterojunction structure of graphene and a two-dimensional material, which is capable of improving quality and a yield.

Embodiments of the inventive concepts may further provide a method for selectively forming a two-dimensional material on graphene.

In an aspect, a method for forming a heterojunction structure may include providing a graphene pattern on a substrate, applying a current to the graphene pattern to heat the graphene pattern, and forming a two-dimensional material layer on the graphene pattern.

In some embodiments, the graphene pattern may be heated to a temperature of about 300° C. to about 500° C. by the current.

In some embodiments, the forming of the two-dimensional material layer may be performed in a state in which the graphene pattern is heated.

In some embodiments, a temperature of the graphene pattern may be higher than a temperature of the substrate during the forming of the two-dimensional material layer.

In some embodiments, the two-dimensional material layer may include at least one of a two-dimensional chalcogenide, a two-dimensional oxide, hexagonal boron nitride (h-BN), black phosphorus (BP), or phosphorene.

In some embodiments, the applying of the current to the graphene pattern and the forming of the two-dimensional material layer may be performed simultaneously for at least a certain time.

In some embodiments, the applying of the current to the graphene pattern may be started before the forming of the two-dimensional material layer is started and may be finished after the forming of the two-dimensional material layer is completed.

In some embodiments, the two-dimensional material layer may be selectively formed on the graphene pattern.

In some embodiments, the two-dimensional material layer may be formed on the substrate, and the number of defects of the two-dimensional material layer formed on the graphene pattern may be less than the number of defects of the two-dimensional material layer formed on the substrate.

In some embodiments, the forming of the two-dimensional material layer may be performed in a furnace, and the furnace may be heated to a temperature of about 700° C. to about 1000° C. when the two-dimensional material layer is formed.

In some embodiments, the method may further include providing electrodes electrically connected to both ends of the graphene pattern, respectively.

In some embodiments, the electrodes may include graphene. The providing of the graphene pattern and the electrodes may include forming a graphene layer on the substrate, and patterning the graphene layer.

In some embodiments, each of the electrodes may extend in a first direction, and the graphene pattern may extend in a second direction intersecting the first direction.

In some embodiments, a width of each of the electrodes may be greater than a width of the graphene pattern.

### BRIEF DESCRIPTION OF THE DRAWINGS

The inventive concepts will become more apparent in view of the attached drawings and accompanying detailed description.

FIG. 1 is a flowchart illustrating a method for forming a heterojunction structure according to example embodiments of the inventive concepts.

FIGS. 2 to 4 are perspective views illustrating a method for forming a heterojunction structure according to example embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a”, “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Similarly, it will be understood that when an element such as a layer, region or substrate is referred to as being “on” another element, it can be directly on the other element or intervening elements may be present. In contrast, the term “directly” means that there are no intervening elements. Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes.

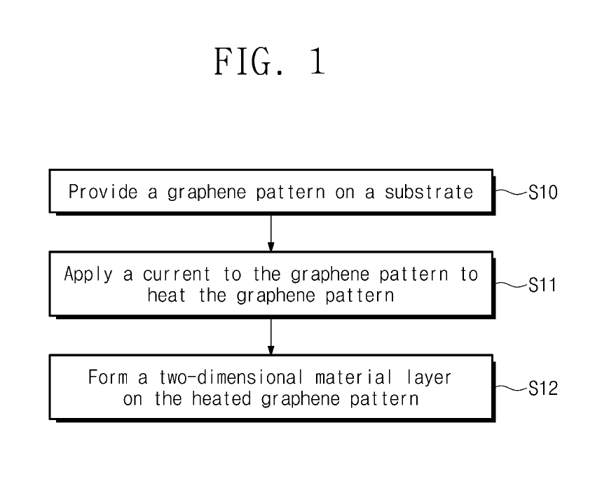

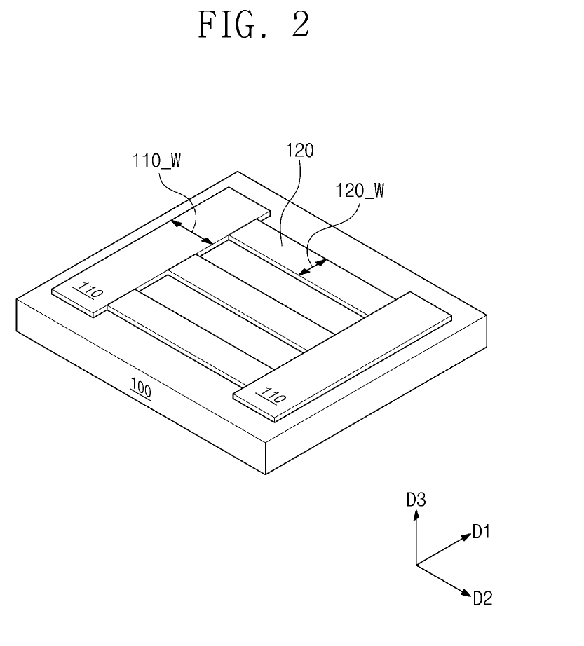

FIG. 1 is a flowchart illustrating a method for forming a heterojunction structure according to example embodiments of the inventive concepts. FIGS. 2 to 4 are perspective views illustrating a method for forming a heterojunction structure according to example embodiments of the inventive concepts.

Referring to FIGS. 1 and 2, electrodes 110 and graphene patterns 120 may be provided on a substrate 100.

The substrate 100 may be a semiconductor substrate, a glass substrate, or a polymer substrate. The semiconductor substrate may be, for example, a silicon substrate, a germanium substrate, a silicon-on-insulator (SOI) substrate, a germanium-on-insulator (GeOI) substrate, or a silicon-germanium substrate. The glass substrate may include at least one of, for example, silicon oxide, aluminum oxide, zinc oxide, sodium oxide, potassium oxide, magnesium oxide, barium oxide, or boron oxide. The polymer substrate may include at least one of, for example, polyester (PET), polyethylenenapthalate (PEN), polycarbonate (PC), polyetherimide (PEI), polyethersulfone (PES), polyetheretherketone (PEEK), or polyimide. However, embodiments of the inventive concepts are not limited thereto. In certain embodiments, the kind of the substrate 100 may be variously changed.

A pair of the electrodes 110 may be provided on the substrate 100. The pair of electrodes 110 may be spaced apart from each other. In some embodiments, each of the pair of electrodes 110 may extend in a first direction D1 substantially parallel to a top surface of the substrate 100, and the pair of electrodes 110 may be spaced apart from each other in a second direction D2 which intersects the first direction D1 and is substantially parallel to the top surface of the substrate 100. For example, each of the electrodes 110 may have a linear shape extending in the first direction D1. Each of the pair of electrodes 110 may have a width 110_W in a direction which is perpendicular to its extending direction and is substantially parallel to the top surface of the substrate 100. However, embodiments of the inventive concepts are not limited thereto. In certain embodiments, the shapes of the electrodes 110 may be variously modified or changed.

The pair of electrodes 110 may include a conductive material. For example, the pair of electrodes 110 may include graphene, a metal, or a semiconductor doped with dopants.

The providing of the pair of electrodes 110 may include forming an electrode layer (not shown) on the substrate 100 and patterning the electrode layer. In some embodiments, the patterning of the electrode layer may include forming mask patterns (not shown) on the electrode layer and etching the electrode layer using the mask patterns as etch masks. In other embodiments, the electrode layer may be patterned using a laser patterning process.

The graphene pattern 120 may be provided on the substrate 100 (S10). In some embodiments, the graphene pattern 120 may be provided in plurality, as illustrated in FIG. 2. However, embodiments of the inventive concepts are not limited thereto. In certain embodiments, a single graphene pattern 120 may be provided on the substrate 100, unlike FIG. 2.

Both ends of the graphene pattern 120 may be electrically connected to the pair of electrodes 110, respectively. When the graphene pattern 120 is provided in plurality, the graphene patterns 120 may be connected in parallel between the pair of electrodes 110. In some embodiments, the graphene pattern 120 may extends in the second direction D2. For example, the graphene pattern 120 may have a linear shape extending in the second direction D2. In these embodiments, when the graphene pattern 120 is provided in plurality, the graphene patterns 120 may be spaced apart from each other in the first direction D1. The graphene pattern 120 may have a width 120_W in a direction which is perpendicular to its extending direction and is substantially parallel to the top surface of the substrate 100. In some embodiments, the width 120_W of the graphene pattern 120 may be smaller than the width 110_W of each of the electrodes 110. However, embodiments of the inventive concepts are not limited thereto. In certain embodiments, the shape of the graphene pattern 120 may be variously modified or changed.

The graphene pattern 120 may include graphene of which a thickness ranges from a thickness of one layer to a thickness of five stacked layers. However, embodiments of the inventive concepts are not limited thereto. In certain embodiments, the thickness of the graphene pattern 120 may be variously changed in a range in which the graphene pattern 120 is sufficiently heated by a current applied into the graphene pattern 120.

The providing of the graphene pattern 120 may include forming a graphene layer (not shown) on the substrate 100 and patterning the graphene layer. In some embodiments, the patterning of the graphene layer may include forming mask patterns (not shown) on the graphene layer and etching the graphene layer using the mask patterns as etch masks. In other embodiments, the graphene layer may be patterned using a laser patterning process.

In the embodiments in which the electrodes 110 include graphene, the electrodes 110 may be provided by the process of providing the graphene pattern 120. In other words, in these embodiments, the electrodes 110 and the graphene pattern 120 may be formed at the same time. For example, the providing of the electrodes 110 and the graphene pattern 120 may include forming a graphene layer (not shown) on the substrate 100 and performing a patterning process to form the electrodes 110 and the graphene pattern 120 from the graphene layer at the same time.

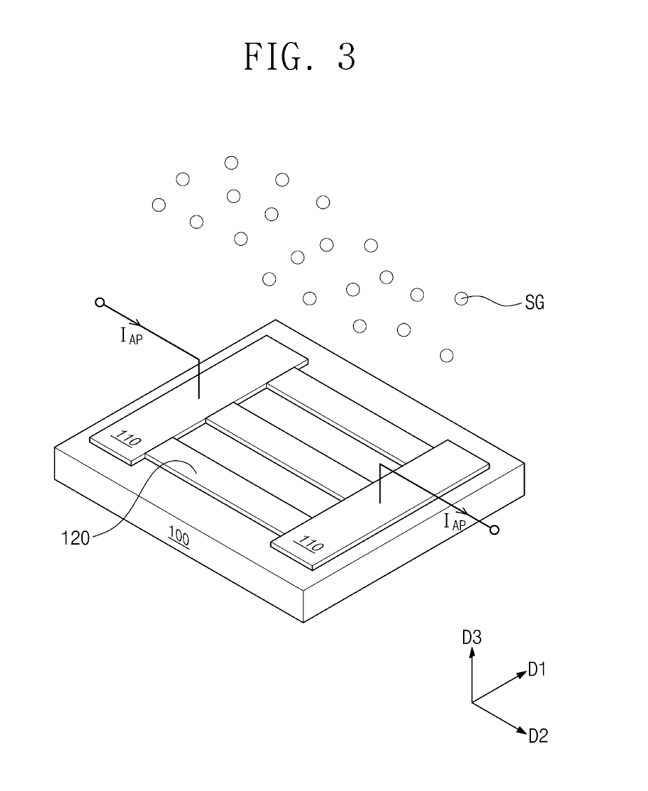

Referring to FIGS. 1 and 3, a current I_{AP} may be applied to the graphene pattern 120 through the electrodes 120, and thus the graphene pattern 120 may be heated (S11). The graphene pattern 120 may be heated due to Joule's heat generated by the applied current I_{AP}. For example, the graphene pattern 120 may be heated to a temperature of about 300° C. to about 500° C. by the applied current I_{AP}.

The electrodes 110 may also be heated by the applied current I_{AP}. However, a temperature of the electrodes 110 heated by the applied current I_{AP} may be lower than the temperature of the graphene pattern 120 heated by the applied current I_{AP}. For example, in the embodiments in which the electrodes 110 include graphene, the temperature of the electrodes 110 heated by the applied current I_{AP} may be lower than the temperature of the graphene pattern 120 heated by the applied current I_{AP}. This may be because the widths 110_W of the electrodes 110 are greater than the width 120_W of the graphene pattern 120.

Referring to FIGS. 1, 3, and 4, a two-dimensional material layer 130 may be formed on the graphene pattern 120 (S12). The two-dimensional material layer 130 may include at least one of, for example, a two-dimensional chalcogenide, a two-dimensional oxide, hexagonal boron nitride (h-BN), black phosphorus (BP), or phosphorene. The two-dimensional chalcogenide may be a transition metal dichalcogenide (TMD; e.g., MoS₂, WS₂, MoSe₂, WSe₂, MoTe₂, WTe₂, ZrS₂, or ZrSe₂), a transition metal trichalcogenide (TMT; e.g., TiS₃, TiSe₃, ZrS₃, or ZrSe₃), a metal phosphorus trichacogenide (MPT; e.g., MnPS₃, FePS₃, CoPS₃, or NiPS₃), or a metal monochalcogenide (MMC; e.g., GaS, GaSe, or InSe). The two-dimensional oxide may be MoO₃, WO₃, TiO₂, MnO₂, V₂O₅, TaO₃, or RuO₂.

As illustrated in FIG. 3, the formation of the two-dimensional material layer 130 may include supplying source materials (e.g., source gases) SG onto the heated graphene pattern 120. The application of the current I_{AP} to the graphene pattern 120 and the formation of the two-dimensional material layer 130 may be performed simultaneously for at least a certain time. For example, the application of the current I_{AP} to the graphene pattern 120 and the supplying of the source materials SG may be performed simultaneously for at least a certain time. In some embodiments, the application of the current I_{AP} to the graphene pattern 120 may be started before the process of forming the two-dimensional material layer 130 is started (e.g., before the source materials SG are supplied) and may be finished after the process of forming the two-dimensional material layer 130 is completed (e.g., after the supply of the source materials SG is interrupted).

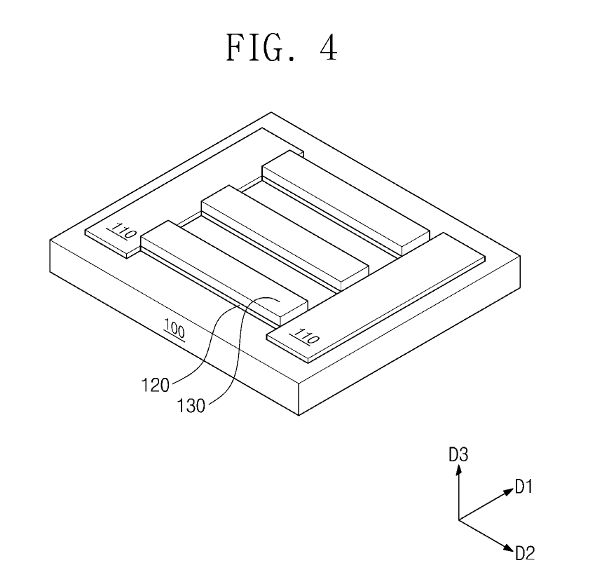

The source materials SG may react on a surface of the heated graphene pattern 120 to form the two-dimensional material layer 130. Since the graphene pattern 120 is heated by the applied current I_{AP}, the temperature of the graphene pattern 120 may be higher than a temperature of the substrate 100 and the temperature of the electrodes 110 during the formation of the two-dimensional material layer 130. Thus, heat energy for the reaction of the source materials SG may be supplied more from the graphene pattern 120 than from the substrate 100 and the electrodes 110. As a result, the two-dimensional material layer 130 may be selectively formed on the graphene pattern 120, as illustrated in FIG. 4. Alternatively, even though the two-dimensional material layer 130 is formed on the substrate 100 and the electrodes 110 unlike FIG. 4, defects of the two-dimensional material layer 130 formed on the graphene pattern 120 may be less than defects of the two-dimensional material layer 130 formed on the substrate 100 and the electrodes 110.

The process of forming the two-dimensional material layer 130 may be performed in a furnace.

In some embodiments, additional heat energy may not be supplied to the furnace during the formation of the two-dimensional material layer 130. For example, the furnace may not be heated during the formation of the two-dimensional material layer 130. According to these embodiments, the source materials SG may react by using the heat energy occurring from the graphene pattern 120.

In other embodiments, additional heat energy may be supplied to the furnace during the formation of the two-dimensional material layer 130. For example, the furnace may be heated to a temperature of about 700° C. to about 1000° C. According to these embodiments, the source materials SG may react by using the heat energy occurring from the graphene pattern 120 and the additional heat energy supplied to the furnace.

Since the two-dimensional material layer 130 is formed on the graphene pattern 120, formation of a heterojunction structure according to embodiments of the inventive concepts may be completed.

According to embodiments of the inventive concepts, the heterojunction structure of the graphene pattern 120 and the two-dimensional material layer 130 may be formed without a laminating process or a transferring process. Thus, it is possible to simplify the processes for forming the heterojunction structure of the graphene pattern 120 and the two-dimensional material layer 130. In addition, since processes of laminating and transferring a two-dimensional material are omitted, it is possible to improve quality and a yield of the heterojunction structure of the graphene pattern 120 and the two-dimensional material layer 130.

Furthermore, according to embodiments of the inventive concepts, the heat energy occurring by the current I_{AP} applied to the graphene pattern 120 may be used in the reaction for the formation of the two-dimensional material layer 130. Thus, the two-dimensional material layer 130 may be selectively formed on the graphene pattern 120. Alternatively, even though the two-dimensional material layer 130 is formed on the substrate 100 and the electrodes 110, defects of the two-dimensional material layer 130 formed on the graphene pattern 120 may be less than defects of the two-dimensional material layer 130 formed on the substrate 100 and the electrodes 110.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A method for forming a heterojunction structure, the method comprising:
providing a graphene pattern on a substrate;
applying a current to the graphene pattern to heat the graphene pattern; and
forming a two-dimensional material layer on the graphene pattern.

2. The method of claim 1, wherein the graphene pattern is heated to a temperature of about 300° C. to about 500° C. by the current.

3. The method of claim 1, wherein the forming of the two-dimensional material layer is performed in a state in which the graphene pattern is heated.

4. The method of claim 1, wherein a temperature of the graphene pattern is higher than a temperature of the substrate during the forming of the two-dimensional material layer.

5. The method of claim 1, wherein the two-dimensional material layer includes at least one of a two-dimensional chalcogenide, a two-dimensional oxide, hexagonal boron nitride (h-BN), black phosphorus (BP), or phosphorene.

6. The method of claim 1, wherein the applying of the current to the graphene pattern and the forming of the two-dimensional material layer are performed simultaneously for at least a certain time.

7. The method of claim 6, wherein the applying of the current to the graphene pattern is started before the forming of the two-dimensional material layer is started, and the applying of the current to the graphene pattern is finished after the forming of the two-dimensional material layer is completed.

8. The method of claim 1, wherein the two-dimensional material layer is selectively formed on the graphene pattern.

9. The method of claim 1, wherein the two-dimensional material layer is formed on the substrate, and
wherein the number of defects of the two-dimensional material layer formed on the graphene pattern is less than the number of defects of the two-dimensional material layer formed on the substrate.

10. The method of claim 1, wherein the forming of the two-dimensional material layer is performed in a furnace, and
wherein the furnace is heated to a temperature of about 700° C. to about 1000° C. when the two-dimensional material layer is formed.

11. The method of claim 1, further comprising:
providing electrodes electrically connected to both ends of the graphene pattern, respectively.

12. The method of claim 11, wherein the electrodes include graphene,
wherein the providing of the graphene pattern and the electrodes comprises:
forming a graphene layer on the substrate; and
patterning the graphene layer.

13. The method of claim 11, wherein each of the electrodes extends in a first direction, and
wherein the graphene pattern extends in a second direction intersecting the first direction.

14. The method of claim 13, wherein a width of each of the electrodes is greater than a width of the graphene pattern.
